(19) United States
(12) Patent Application Publication
(10) Pub. No.: US 2021/0384393 A1
(43) Pub. Date: Dec. 9, 2021

(54) PROCESS METHOD AND DEVICE FOR IMPROVING LED EMISSION LUMINANCE

(71) Applicant: JIANGXI HONGLI TRONIC CO., LTD., NANCHANG (CN)

(72) Inventors: DEWANG RAO, NANCHANG (CN); MINGPENG ZUO, NANCHANG (CN); YIYUAN Li, NANCHANG (CN); MINGWU ZHANG, NANCHANG (CN)

(21) Appl. No.: 17/393,388

(22) Filed: Aug. 3, 2021

(30) Foreign Application Priority Data
Jun. 4, 2020 (CN) 202010501672.6

(51) Int. Cl. H01L 33/60; H01L 33/52; H01L 33/48

(52) U.S. Cl. CPC H01L 33/60; H01L 33/504; H01L 33/483; H01L 33/52

(57) ABSTRACT

A process method for improving LED emission luminance is disclosed. A chip is fixed in a holder through the die attach adhesive, the chip is connected to a functional region of the holder; a high-reflectivity adhesive is filled onto a welding position in the functional region and then baked to dry, a red fluorescent adhesive is filled not higher than step of an inner wall of the holder and then centrifuged, and the stepped design of the holder can effectively prevent the fluorescent adhesive from extending to an upper layer; the first layer red fluorescent adhesive is centrifuged and then baked until it turns into a gel state, and a second layer green fluorescent adhesive is dispensed above the stepped position on the inner wall. The process method of the disclosed can increase the overall emission luminance and the uniformity of emission color of the LED lamp beads

### TECHNICAL FIELD

The present disclosure relates to the LED packaging technical field, and in particular to a process method and device for improving LED emission luminance.

### RELATED ART

Since competition of the LED market has been increasingly intensified, and costs of the LED devices are reduced, the market has increasing demands for low-cost and high-luminance LED devices. With raw materials of current price, the luminance cannot be further optimized, so it is urgent to obtain a low-cost and high-luminance advanced product by means of modifying the holder structures and changing the existing processes.

In conclusion, the present disclosure provides a process method and device for improving LED emission luminance.

### SUMMARY

In view of the disadvantages in the existing technology, a purpose of the present disclosure is to provide a process method and device for improving LED emission luminance, which has the advantages of simple process, reasonable design and convenient use, and thus can improve the luminance and the luminous uniformity of the finished products produced by the existing dispensing processes.

In order to achieve the above purpose, the present disclosure is achieved by providing a process method for improving LED emission luminance, comprising:
(A) a chip is fixed in a bowl-shaped functional region of a holder through a die attach adhesive, after being baked and cured, positive and negative electrodes of the chip are conductively connected to positive and negative functional regions of the holder through a gold bonding wire;
(B) a high-reflectivity adhesive is filled onto a functional region at a bottom of the holder to cover welding joints and an initial plating layer on the bottom of the holder;
(C) the high-reflectivity adhesive is baked at a high temperature and cured into a reflective layer with high reflectivity;
(D) a first layer red fluorescent adhesive is dispensed in the holder with stepped design on its plastic inner wall, and the height of dispensed adhesive should not be higher than the step of the holder, after finishing dispensing, the first layer red fluorescent adhesive is centrifuged, so that red fluorescent powders in the first layer red fluorescent adhesive are evenly distributed above the chip; the first layer red fluorescent adhesive is baked to turn into a gelatin state and taken out after incompletely cured to be jelly shape;
(E) a second layer green fluorescent adhesive is dispensed above the step of the holder, after finishing dispensing, the second layer green fluorescent adhesive is put into the oven and baked, thus to obtain a complete product;
(F) more light emitted from the chip is excited and centrifuged by the high-reflectivity adhesive 7 at the bottom of the holder 6 to distribute evenly on the red fluorescent powders and green fluorescent powders above a surface of the chip 1, thus the luminance and color uniformity are improved.

Preferably, the die attach adhesive is replaced with a solder paste.

The beneficial effects of the present disclosure lies in that the present disclosure can preferentially excite the fluorescent powders located above the chip, so that the excitation effect of the fluorescent powders is maximized, and thus the luminance and color uniformity of the lamp beads have been improved; a high-reflectivity adhesive is dispensed at the bottom layer welded on the holder, so that the reflectivity of the holder bottom has been improved after curing, thus the luminance of the LED lamp beads are increased, and the practicability is higher. The present disclosure has many advantages such as simple structure, reasonable design, and low manufacturing cost.

### BRIEF DESCRIPTION OF THE DRAWINGS

The present disclosure will be described in detail hereafter with reference to the drawings and specific embodiments.

FIG. 1 is a cross-sectional structural view of an LED light emitting device in the prior art.

FIG. 2 is a schematic structural view of a support bowl connecting to a chip, a die attach adhesive, and a gold bonding wire in the LED light emitting device in the prior art.

FIG. 3 is a schematic view of the LED light emitting device in FIG. 1 in the prior art.

FIG. 4 is a cross-sectional structural view of the device according to the present disclosure.

FIG. 5 is a schematic structural view of the support bowl connecting to the chip, the die attach adhesive, and the gold bonding wire in the LED light emitting device according to the present disclosure.

FIG. 6 is a schematic view of the device according to the present disclosure.

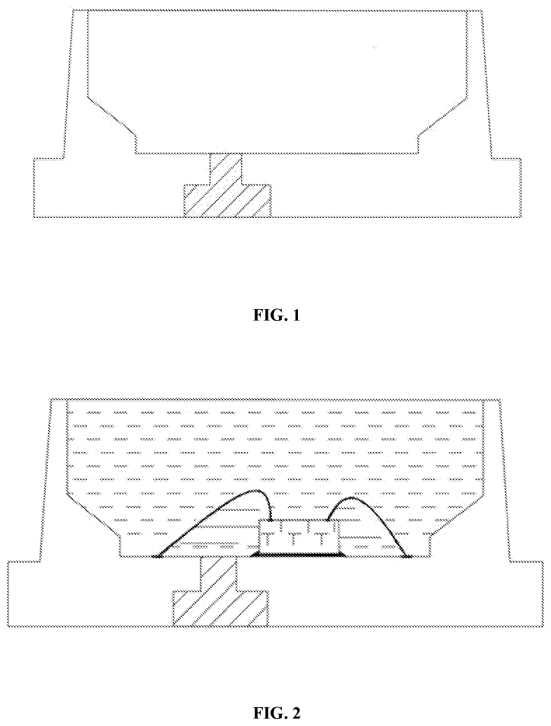

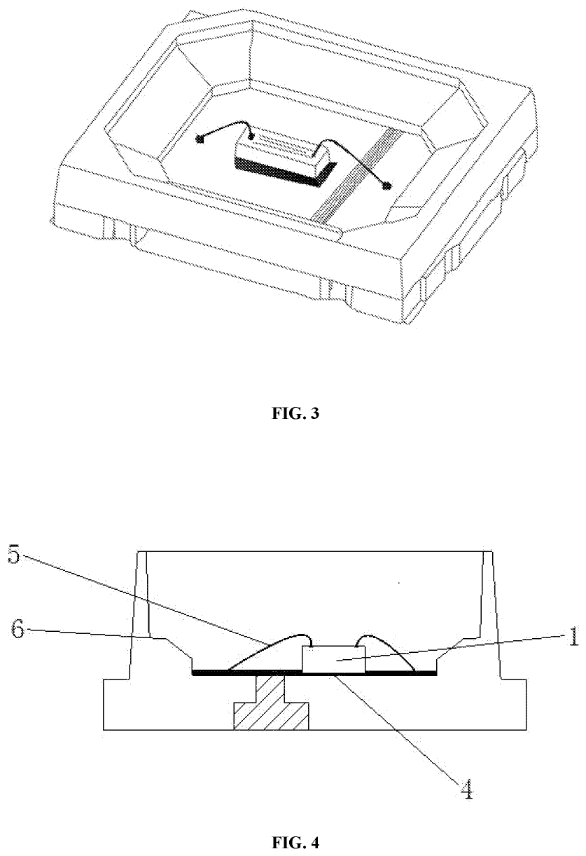

### DETAILED DESCRIPTION

In order to make the technical means, creative features, objectives and effects of the present disclosure easy to understand, the present disclosure will be further explained below in conjunction with the specific embodiments.

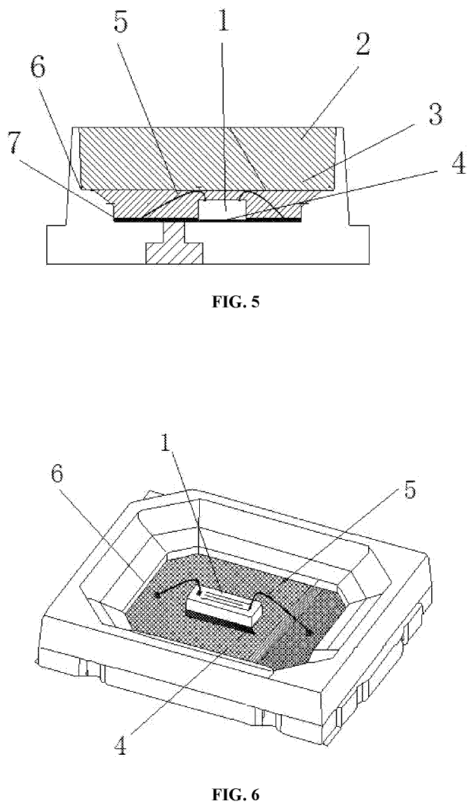

Referring to FIG. 4-6, this specific embodiment adopts the following technical solution: a process method for improving LED emission luminance, comprising the following steps:

(A) a chip 1 is fixed in a bowl-shaped functional region of a holder 6 through a die attach adhesive 4, after being baked and cured, positive and negative electrodes of the chip 1 are conductively connected to positive and negative functional regions of the holder 6 through a gold bonding wire 5;

(B) a high-reflectivity adhesive 7 is filled onto a functional region at a bottom of the holder 6 to cover welding joints and an initial plating layer on the bottom of the holder 6;

(C) the high-reflectivity adhesive 7 is baked at a high temperature and cured into a reflective layer with high reflectivity;

(D) a first layer red fluorescent adhesive 3 is dispensed in the holder 6 with stepped design on its plastic inner wall, and the height of dispensed adhesive should not be higher than the step of the holder 6, after finishing dispensing, the first layer red fluorescent adhesive 3 is centrifuged, so that red fluorescent powders in the first layer red fluorescent adhesive 3 are evenly distributed above the chip 1; the first layer red fluorescent adhesive 3 is baked to turn into a gelatin state and taken out after incompletely cured to be jelly shape;

(E) a second layer green fluorescent adhesive 2 is dispensed above the step of the holder 6, after finishing dispensing, the second layer green fluorescent adhesive 2 is put into the oven and baked, thus to obtain a complete product;

(F) more light emitted from the chip is excited and centrifuged by the high-reflectivity adhesive 7 at the bottom of the holder 6 to distribute evenly on the red fluorescent powders and green fluorescent powders above a surface of the chip 1, thus the luminance and color uniformity are improved.

A device for improving LED emission luminance, comprises a chip 1, a second layer green fluorescent adhesive 2, a first layer red fluorescent adhesive 3, a die attach adhesive 4, a gold bonding wire 5, a holder 6 with stepped designed on its plastic inner wall, and a high-reflectivity adhesive 7. The chip 1 is fixed in a bowl-shaped functional region of the holder 6 through the die attach adhesive 4, and the chip 1 is connected to a conductive position of the functional region of the holder 6 through the gold bonding wire 5 to form a conductive circuit;

the high-reflectivity adhesive 7 is dispensed on the functional region of the holder 6 and at a conductive connection point between the gold bonding wire 5 and the holder 6, and the high-reflectivity adhesive 7 at the bottom of the holder 6 has higher reflectivity after being baked to cure. The first layer red fluorescent adhesive 3 is dispensed not higher than the step on the inner wall of the holder 6, and the step on the inner wall of the holder 6 can effectively prevent a capillary phenomenon of the red fluorescent adhesive 3 from extending to an upper layer; after the dispensed first layer red fluorescent adhesive 3 is centrifuged, red fluorescent powders are evenly distributed above the chip 1. The first layer red fluorescent adhesive 3 is baked into a gelatin state through an oven and then taken out, and the second layer green fluorescent adhesive 2 is dispensed on the first layer red fluorescent adhesive 3 and higher than the step on the inner wall of the holder 6, and then the whole product is placed into the oven and totally baked to obtain a product with higher emission luminance and more uniform luminous color.

A white channel is embedded and fixed on a bowl structure of the holder 6 to divide the holder 6 into a positive electrode region and a negative electrode region. The plastic inner wall of the holder 6 is designed as stepped structure, which can prevent a capillary phenomenon and adhesive of different color dispensed below the step from spreading to an upper layer, so that the red fluorescent powders can be fully distributed above the chip 1 after the red fluorescent adhesive is centrifuged, thus to improve the uniformity of the luminous color and emission luminance. After welding, the high-reflectivity adhesive 7 is dispensed on the functional region of the holder 6 and baked to dry, so that the reflectivity at the holder bottom is increased, and the overall luminance of the lamp beads is further improved.

The working principle of the embodiment is that the high-reflectivity adhesive 7 is filled onto the functional region at the bottom of the holder 7 to cover the welding joints and an initial plating layer on the bottom of the holder 6, so as to increase the reflectivity at the holder bottom. The high-reflectivity adhesive 7 can increase the reflectivity, thereby further enhancing the luminance. Furthermore, through two times of adhesive dispensing, in the holder 6 with step designed on its inner wall, the red fluorescent adhesive 3 is first dispensed below the step on the inner wall of the holder 6, and the stepped design can effectively prevent the adhesive from spreading to the upper layer through the capillary phenomenon. The red fluorescent powers can be evenly distributed above the surface of the chip 1 through centrifugation, the red fluorescent adhesive is baked to turn into a gelatin state and then taken out, and next the green fluorescent adhesive 2 is dispensed, thus the color consistency is good, and the luminance is improved obviously.

In the embodiment, the high-reflectivity adhesive is preferentially filled onto the already wire-bonded functional region of holder, and the high-reflectivity adhesive can cover the bottom functional region and the welding joints on the functional region to obtain higher reflectivity when the chip emits light. By using the holder with step designed on its inner wall, the red fluorescent adhesive is first dispensed at the position not higher than the step on the inner wall of the holder, which can effectively prevent the fluorescent adhesive from extending to the upper layer through the capillary phenomenon. The red fluorescent adhesive is centrifuged and baked to turn into a gelatin state and then taken out, the green fluorescent adhesive is then dispensed and totally baked to obtain a finished product, so that the emission luminance and the uniformity luminous color have been improved.

The process method of the embodiment according to the present disclosure can improve the reflectivity at the bottom of the LED holder, increase the luminance of the LED lamp beads, excite the luminance of the fluorescent powders maximally through layered dispensing, and can improve the color uniformity of the light source at the same time, and the practicability is higher. The present disclosure has many advantages such as simple structure, reasonable design, and low manufacturing cost.

The basic principles, main features and advantages of the present disclosure have been illustrated and described above. Those skilled in the art should understand that the present disclosure is not limited to the above-mentioned embodiments. The above-mentioned embodiments and descriptions only illustrate the principles of the present disclosure. The present disclosure will have various changes and improvements without departing from the spirit and scope of the present disclosure, and all these changes and improvements fall within the scope of the present disclosure. The protection scope of the present disclosure is defined by the appended claims and their equivalents.

What is claimed is:

1. A process method for improving LED emission luminance, comprising:
(A) a chip is fixed in a bowl-shaped functional region of a holder through a die attach adhesive, after being baked and cured, positive and negative electrodes of the chip are conductively connected to positive and negative functional regions of the holder through a gold bonding wire;
(B) a high-reflectivity adhesive is filled onto a functional region at a bottom of the holder to cover welding joints and an initial plating layer on the bottom of the holder;
(C) the high-reflectivity adhesive is baked at a high temperature and cured into a reflective layer with high reflectivity;
(D) a first layer red fluorescent adhesive is dispensed in the holder with stepped design on its plastic inner wall, and the height of dispensed adhesive should not be higher than the step of the holder, after finishing dispensing, the first layer red fluorescent adhesive is centrifuged, so that red fluorescent powders in the first layer red fluorescent adhesive are evenly distributed above the chip; the first layer red fluorescent adhesive is baked to turn into a gelatin state and taken out after incompletely cured to be jelly shape;
(E) a second layer green fluorescent adhesive is dispensed above the step of the holder, after finishing dispensing, the second layer green fluorescent adhesive is put into the oven and baked, thus to obtain a complete product;
(F) more light emitted from the chip is excited and centrifuged by the high-reflectivity adhesive 7 at the bottom of the holder 6 to distribute evenly on the red fluorescent powders and green fluorescent powders above a surface of the chip 1, thus the luminance and color uniformity are improved.

2. A device for improving LED emission luminance, comprising: a chip, a second layer green fluorescent adhesive, a first layer red fluorescent adhesive, a die attach adhesive, a gold bonding wire, a holder with stepped designed on its plastic inner wall, and a high-reflectivity adhesive;
wherein the chip is fixed in a bowl-shaped functional region of the holder through the die attach adhesive, and the chip is connected to a conductive position of the functional region of the holder through the gold bonding wire to form a conductive circuit;
the high-reflectivity adhesive is dispensed on the functional region of the holder and at a conductive connection point between the gold bonding wire and the holder, the high-reflectivity adhesive at the bottom of the holder has higher reflectivity after being baked to cure; the first layer red fluorescent adhesive is dispensed not higher than the step on the inner wall of the holder, and the step on the inner wall of the holder can effectively prevent the red fluorescent adhesive from extending to an upper layer through capillary phenomenon;
after the dispensed first layer red fluorescent adhesive is centrifuged, red fluorescent powders are evenly distributed above the chip; the first layer red fluorescent adhesive is baked into a gelatin state through an oven and then taken out,
the second layer green fluorescent adhesive is dispensed on the first layer red fluorescent adhesive, and then the whole product is placed into the oven and totally baked to obtain a product with higher emission luminance and more uniform luminous color.

3. The device for improving LED emission luminance according to claim 2, wherein a white channel is embedded and fixed on a bowl structure of the holder to divide the holder into a positive electrode region and a negative electrode region, and the plastic inner wall of the holder is designed as stepped structure.

4. The device for improving LED emission luminance according to claim 2, wherein the die attach adhesive is replaced with a solder paste.
